(19) United States
(12) Patent Application Publication
(10) Pub. No.: US 2016/0002439 A1
(43) Pub. Date: Jan. 7, 2016

(54) APPARATUS, COMPOSITION FOR ADHESIVE, AND ADHESIVE SHEET

(71) Applicant: SUMITOMO BAKELITE CO., LTD., Tokyo (JP)

(72) Inventors: Mika Tsuda, Tokyo (JP); Daisuke Kitahara, Tokyo (JP); Yoji Shirato, Tokyo (JP); Kazuya Kitagawa, Tokyo (JP); Akihiko Tobisawa, Tokyo (JP)

(73) Assignee: SUMITOMO BAKELITE CO., LTD., Tokyo (JP)

(21) Appl. No.: 14/769,946

(22) PCT Filed: Jan. 22, 2014
(86) PCT No.: PCT/JP2014/051205

§ 371 Date: Aug. 24, 2015

(30) Foreign Application Priority Data
Mar. 7, 2013 (JP) 2013-045500

(51) Int. Cl. C08K 3/38; H05K 7/20; C09J 147/00

(52) U.S. Cl. CPC C08K 3/38; C09J 147/00; H05K 7/2039; C08K 2003/385

(57) ABSTRACT

An apparatus (1) includes a supporting base material (12) that supports an element (11), a heat-dissipating member (13) on which the supporting base material (12) is installed, and an adhesive layer (14) disposed between the heat-dissipating member (13) and the supporting base material (12). The glass transition temperature of the adhesive layer (14) is equal to or lower than −30° C.

### TECHNICAL FIELD

The present invention relates to an apparatus, a composition for an adhesive, and an adhesive sheet.

### BACKGROUND ART

In the related art, a semiconductor device is known in which a semiconductor element is mounted on a support such as a lead frame and the support and a heat-dissipating member are closely attached to each other through an adhesive layer.

For example, Patent Document 1 discloses a semiconductor device in which a semiconductor element is mounted on a support such as a lead frame and the support and a heat-transfer metal layer connected to a heat sink are adhered to each other using an insulating resin adhesive layer.

### RELATED DOCUMENT

### Patent Document

[Patent Document 1] Japanese Unexamined Patent Publication No. 2011-216619

### SUMMARY OF THE INVENTION

In Patent Document 1, there are cases in which the difference between the linear expansion coefficient of the support that supports the semiconductor element and the linear expansion coefficient of the heat-transfer metal layer becomes significant. In this case, since the expansion and shrinkage ratio of the support due to a change in the environmental temperature and the expansion and shrinkage ratio of the heat-transfer metal layer differ, there is a concern that the insulating resin adhesive layer may be peeled off from the support or the heat-transfer metal layer. In a case in which the insulating resin adhesive layer is peeled off from the support or the heat-transfer metal layer, it becomes difficult to transfer heat from the semiconductor element to the heat-transfer metal layer and the durability of the semiconductor device degrades.

According to the present invention, there is provided an apparatus including:

a supporting base material that supports an element;

a heat-dissipating member on which the supporting base material is installed; and

an adhesive layer disposed between the heat-dissipating member and the supporting base material,

in which a glass transition temperature of the adhesive layer is equal to or lower than −30° C.

According to the present invention, since the glass transition temperature of the adhesive layer is equal to or lower than −30° C., the adhesive layer turns into a rubber state in a wide temperature range. Therefore, even when a difference is caused between the expansion and shrinkage ratio of the heat-dissipating member and the expansion and shrinkage ratio of the supporting base material due to a change in the environmental temperature, it is possible to mitigate the difference using the adhesive layer. Therefore, it is possible to produce an apparatus having high durability.

In addition, according to the present invention, it is also possible to provide a composition for an adhesive and an adhesive sheet.

That is, according to the present invention, there is provided a composition for an adhesive which adheres a supporting base material that supports an element and a heat-dissipating member together, in which Tg is −30° C. or lower after the composition is cured at 150° C. for 1 hour.

Furthermore, according to the present invention, there is also provided an adhesive sheet obtained by shaping the above-described composition for adhesion into a sheet shape.

According to the present invention, an apparatus having high durability, and a composition for an adhesive and an adhesive sheet which are used for the apparatus having high durability are provided.

### BRIEF DESCRIPTION OF THE DRAWINGS

The above-described object and other objects, characteristics, and advantages will be further clarified using preferred embodiments described below and the accompanying drawings below.

FIG. 1 shows a cross-section of an apparatus according to an embodiment of the present invention.

FIG. 2 is a cross-section of an apparatus according to a modification example of the present invention.

### DESCRIPTION OF EMBODIMENTS

Hereinafter, embodiments of the present invention will be described on the basis of the drawings. Meanwhile, in all the drawings, the same component will be given the same reference and detailed description thereof will not be repeated.

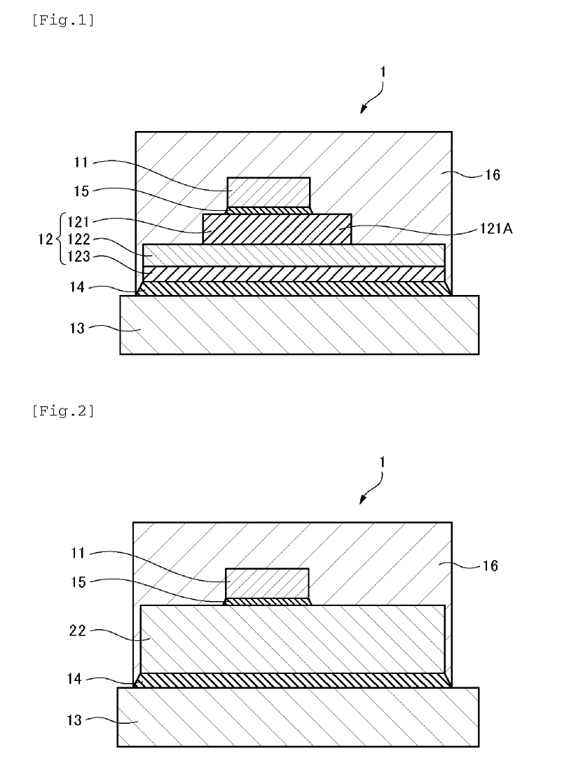

The present embodiment will be described with reference to FIG. 1.

First, the overview of an apparatus 1 of the present embodiment will be described.

The apparatus 1 includes a supporting base material 12 that supports an element 11;

a heat-dissipating member 13 on which the supporting base material 12 is installed; and

an adhesive layer 14 disposed between the heat-dissipating member 13 and the supporting base material 12,

in which the glass transition temperature of the adhesive layer 14 is equal to or lower than −30° C.

Next, the apparatus 1 will be described in detail.

In the present embodiment, the apparatus 1 is a semiconductor device, for example, a semiconductor power module.

The element 11 is a semiconductor element, for example, a semiconductor element such as an insulated-gate bipolar transistor (IGBT).

The element 11 is joined to the supporting base material 12 through a solder 15.

On the supporting base material 12, the element 11 is mounted. In the present embodiment, the supporting base material 12 includes a lead frame 121, an insulating sheet 122, and a heat-transfer layer 123.

The lead frame 121 includes a die pad section 121A, an inner lead (not shown) connected to the die pad section 121A, and an outer lead connected to the inner lead. The lead frame 121 supports the element 11 at the die pad section 121A. The die pad section 121A is electrically connected to the element 11 through the solder 15. The lead frame 121 may be a conductive member made of, for example, a metal such as Cu.

The insulating sheet 122 is for insulating the heat-transfer layer 123 from the lead frame 121. The insulating sheet 122 is made of a resin material.

For example, the insulating sheet 122 includes a resin having an ester bond, which is a resin component, and a heat-transferring filler.

Examples of the resin having an ester bond include poly(meth)acrylic acid ester-based macromolecular compounds containing either or both butyl acrylate and ethyl acrylate as main raw material components (so-called acrylic rubber).

In addition, as the heat-transferring filler, boron nitride, alumina, and the like can be used.

Preferably, the content of the heat-transferring filler is in a range of 50 to 60 volume % and the content of the resin component is in a range of 40 to 50 volume % with respect to the entire insulating sheet 122.

In the present embodiment, the insulating sheet 122 has a larger planar shape than the die pad section in the lead frame 121 and protrudes from the outer circumference of the die pad section 121A when the planar view of the apparatus 1 is seen in a direction in which the element 11, the supporting base material 12, the adhesive layer 14, and the heat-dissipating member 13 are laminated.

The heat-transfer layer 123 is disposed between the adhesive layer 14 and the insulating sheet 122 and is in direct contact with the adhesive layer 14.

The heat-transfer layer 123 transfers heat from the element 11 to the heat-dissipating member 13. The heat-transfer layer 123 is made of, for example, a metal such as Cu. The heat-transfer layer 123 is a sheet-shaped member and is almost as large as the insulating sheet 122.

The adhesive layer 14 is a layer for adhering the supporting base material 12 to the heat-dissipating member 13. The thickness of the adhesive layer 14 is, for example, in a range of 10 to 100 μm. When the thickness of the adhesive layer 14 is set to equal to or less than 100 μm, it is possible to facilitate the transfer of heat from the element 11 to the heat-dissipating member 13.

Here, the composition of the adhesive layer 14 will be described.

The adhesive layer 14 is obtained by thermally curing a composition for an adhesive including a thermosetting resin (A), a curing agent (B), and an inorganic filler (C). That is, the adhesive layer 14 has a C-stage shape including a thermally-cured curable resin.

As the thermosetting resin (A), any one or more of an epoxy resin, an unsaturated polyester, and an acrylic resin are preferably used. Among them, an epoxy resin is preferably used.

The epoxy resin is, for example, an epoxy resin having an aromatic ring structure or an alicyclic structure (an alicyclic carbon ring structure) and examples thereof include bisphenol-type epoxy resins such as a bisphenol A-type epoxy resin, a bisphenol F-type epoxy resin, a bisphenol S-type epoxy resin, a bisphenol E-type epoxy resin, a bisphenol M-type epoxy resin, a bisphenol P-type epoxy resin, and a bisphenol Z-type epoxy resin, novolac-type epoxy resins such as a phenol novolac-type epoxy resin, a cresol novolac-type epoxy resin, and a tetraphenol ethane novolac-type epoxy resin, biphenyl-type epoxy resins, aryl alkylene-type epoxy resins such as a phenol aralkyl-type epoxy resin having a biphenylene skeleton, and naphthalene-type epoxy resins. The above-described epoxy resins can be used singly and two or more epoxy resins can be used in combination.

In addition, in order to set the glass transition temperature of the adhesive layer 14 to −30° C. or lower, an aliphatic epoxy resin not having an aromatic ring structure is preferably used as the epoxy resin. In addition, from the viewpoint of setting the storage elastic modulus of the adhesive layer 14 to a predetermined range described below, a di- or more-functional aliphatic epoxy resin having two or more glycidyl groups is preferred.

Furthermore, the aliphatic epoxy resin is preferably in a liquid phase at ordinary temperature. Specifically, the viscosity of the aliphatic epoxy resin is preferably in a range of 10 to 30 Pa·s at 25° C.

The above-described aliphatic epoxy resin is preferably an epoxy resin expressed by Chemical Formulae (1) to (10) and preferably includes at least any one of the epoxy resins.

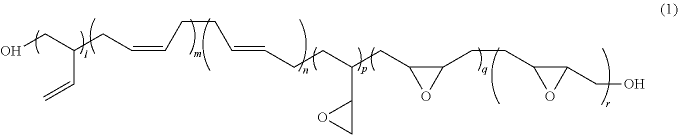

(In Formula (1), l, m, n, p, q, and r are integers of 0 or greater except for a case in which 1, m, and n are all 0 and a case in which p, q, and r are all 0. Among them, it is preferable that l=1 to 5, m=5 to 20, n=0 to 8, p=0 to 8, q=3 to 12, and r=0 to 4.)

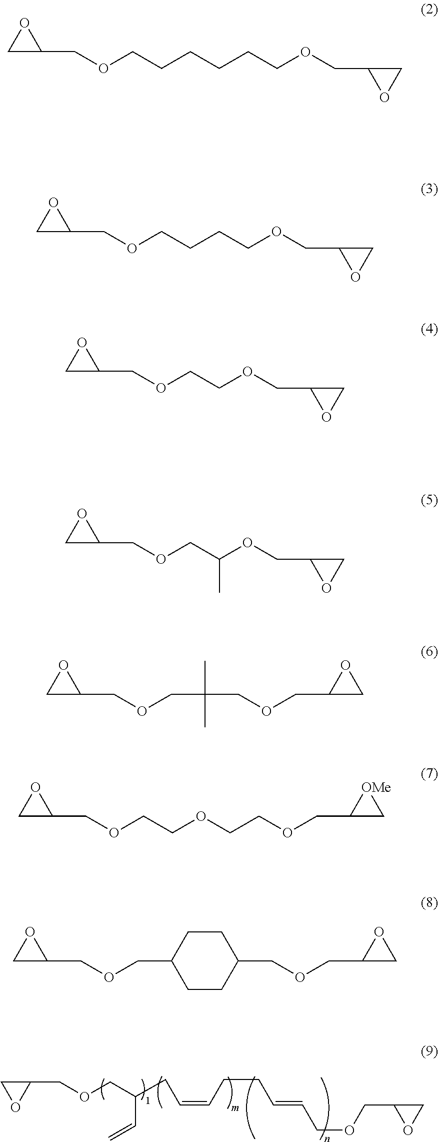

(In Formula (9), l, m, and n are integers of 0 or greater except for a case in which l, m, and n are all 0. Among them, it is preferable that l=1 to 12, m=8 to 30, and n=0 to 10.)

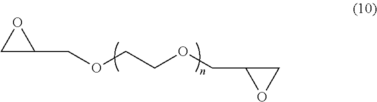

(In Formula (10), n is an integer of 1 or greater and, among them, is preferably 2 to 15.)

Examples of the unsaturated polyester include substance obtained by reacting any one or more polyvalent alcohols such as ethylene glycol, dipropylene glycol, 1,3-butanediol, hydrogenated bisphenol A, neopentyl glycol, isopentyl glycol, and 1,6-hexanediol with any one or more unsaturated dibasic acids such as maleic acid, maleic acid anhydride, fumaric acid, and itaconic acid and, furthermore, copolymerizing the resulting product and any one or more vinyl monomer such as styrene, t-butyl styrene, divinylbenzene, diarylphthalate, vinyl toluene, and acrylic acid esters.

The acrylic resin is a compound having a (meth)acryloyl group in the molecule and is a resin that forms a three-dimensional network structure and is cured when the (meth)acryloyl group is reacted. The acrylic resin needs to have one or more (meth)acryloyl groups in the molecule and preferably has two or more (meth)acryloyl groups.

The acrylic resin is not particularly limited and examples thereof include polymers including one or more esters of acrylic acids or methacrylic acids having a linear or branched alkyl group having 30 or less carbon atoms, particularly, 4 to 18 carbon atoms and the like. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, a dodecyl group, and the like. In addition, other monomers that form the polymer are not particularly limited and examples thereof include acrylic acid, methacrylic acid, carboxyethyl acrylate, carboxypentyl acrylate, hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methylacrylate.

The content of the thermosetting resin (A) is preferably equal to or more than 20 mass % and equal to or less than 50 mass % of a resin composition constituting the adhesive layer 14 and, among them, the content thereof is preferably equal to or more than 30 mass % and equal to or less than 45 mass %.

The content of the aliphatic epoxy resin included in the thermosetting resin (A) (for example, the total content of one or more epoxy resins selected from Chemical Formulae (1) to (10)) is preferably equal to or more than 50 mass % and equal to or less than 80 mass % with respect to the entire thermosetting resin (A). Among them, the total content thereof is preferably equal to or less than 75 mass %.

Examples of the curing agent (B) (curing catalyst) include organic metal salts such as zinc naphthenate, cobalt naphthenate, tin octylate, cobalt octylate, bisacetylacetonate cobalt (II), and trisacetylacetonate cobalt (III), tertiary amines such as triethylamine, tributylamine, and diazabicyclo[2,2,2]octane, imidazoles such as 2-phenyl-4-methylimidazole, 2-ethyl-4-methylimidazole, 2-ethyl-4-ethylimidazole, 2-phenyl-4-methyl-5-hydroxyimidazole, 2-phenyl-4,5-dihydroxyimidazole, 1,2-dimethylimidazole, 1-benzyl-2-phenylimidazole, and 1-cyanoethyl-2-ethyl-4-methylimidazole, organic phosphorous compounds such as triphenyl phosphine, tri-p-tolylphosphine, tetraphenylphosphonium•tetraphenyl borate, triphenylphosphine•triphenylborane, and 1,2-bis-(diphenylphosphino)ethane, phenol compounds such as phenol, bisphenol A, and nonylphenol, organic acids such as acetic acid, benzoic acid, salicylic acid, and p-toluene sulfonic acid, and mixtures thereof. As the curing catalyst, the above described curing agents, including derivatives thereof, can be used singly or two or more curing agents, including derivatives thereof, can also be used in combination.

Among them, a curing catalyst which is in a liquid phase at 25° C. is preferably used. Specifically, imidazoles which are in a liquid phase at 25° C. are preferably used and examples thereof include 2-ethyl-4-methylimidazole, 1,2-dimethylimidazole, 1-benzyl-2-phenylimidazole, and 1-cyanoethyl-2-ethyl-4-methylimidazole.

When the above-described liquid-phase curing catalyst is used and the above-described liquid-phase aliphatic epoxy resin is used, it is possible to obtain a liquid-phase composition for an adhesive including no solvent. In addition, when the adhesive layer 14 is formed using the liquid-phase composition for an adhesive including no solvent, it is possible to suppress the generation of voids in the adhesive layer 14 due to volatilization. When voids are formed in the adhesive layer 14, the transfer of heat to the heat-dissipating member 13 is hindered; however, when the generation of voids in the adhesive layer 14 is suppressed, it is possible to reliably transfer heat from the adhesive layer 14 to the heat-dissipating member 13.

The content of the curing agent is not particularly limited, but is preferably in a range of equal to or more than 0.05 mass % and equal to or less than 5 mass %, and particularly preferably in a range of equal to or more than 0.2 mass % and equal to or less than 2 mass % of the entire composition constituting the adhesive layer 14.

Examples of the inorganic filler (C) include silicates such as talc, fired clay, non-fired clay, mica, and glass, oxides such as titanium oxide, alumina, silica, molten silica, boehmite, and magnesium oxide, carbonates such as calcium carbonate, magnesium carbonate, and hydrotalcite, hydroxides such as aluminum hydroxide, magnesium hydroxide, and calcium hydroxide, sulfates or sulfites such as barium sulfate, calcium sulfate, and calcium sulfite, borates such as zinc borate, barium metaborate, aluminum borate, calcium borate, and sodium borate, nitrides such as aluminum nitride, boron nitride, silicon nitride, and carbon nitride, titanates such as strontium titanate and barium titanate, and the like. The above-described inorganic fillers can be used singly or two or more inorganic fillers can also be used in combination.

Among them, in order to improve the heat-transferring property of the adhesive layer 14, the composition for an adhesive preferably includes a heat-transferring filler. As the heat-transferring filler, any one or more of alumina, boron nitride, boehmite, aluminum nitride, and magnesium oxide can be used.

Among them, the composition for an adhesive preferably includes alumina and boron nitride as the heat-transferring filler.

In addition, as the alumina, large-grain-diameter alumina having an average particle diameter of equal to or more than 18 μm is preferably used. The upper limit value of the average particle diameter of the alumina is, for example, 50 μm.

Meanwhile, as the boron nitride, an agglomerate of boron nitride particles is preferably used and an agglomerate having an average particle diameter in a range of 1 to 10 μm is preferably used. Among them, an agglomerate of boron nitride having an average particle diameter of equal to or less than 7 μm, particularly, equal to or less than 5 μm is preferably used.

When an attempt is made to achieve a desired heat conductivity using the above-described large-grain-diameter alumina alone, due to the high Mohs hardness of the alumina, the elastic modulus of the adhesive layer 14 becomes high and it becomes difficult to obtain an elastic modulus in a desired range described below.

On the contrary, when the above-described large-grain-diameter alumina and the agglomerate of boron nitride having a lower Mohs hardness than the alumina are used in combination, it becomes possible to decrease the elastic modulus of the adhesive layer 14.

In addition, when an attempt is made to achieve a desired heat conductivity using the above-described agglomerate of boron nitride alone, the viscosity of the composition for an adhesive becomes high and usability deteriorates.

On the contrary, when the above-described large-grain-diameter alumina and the agglomerate of boron nitride are used in combination, it becomes possible to decrease the viscosity of the composition for an adhesive.

In addition, when the above-described agglomerate of boron nitride is used, it is possible to make the heat conductivity uniform in the thickness direction and the in-plane direction of the adhesive layer 14.

Here, the average particle diameter can be measured as described below.

The inorganic filler (C) is dispersed in water through a 1-minute ultrasonic treatment using a laser diffraction particle size analyzer SALD-7000 and the particle diameters are measured. In addition, the d50 value is used as the average particle diameter.

In a case in which the large-grain-diameter alumina and the agglomerate of boron nitride are used, the mass ratio of the large-grain-diameter alumina to the agglomerate of boron nitride is preferably set to 1.5 to 3.

Furthermore, the content of the inorganic filler (C) is preferably in a range of equal to or more than 40 mass % and equal to or less than 70 mass %, and particularly preferably in a range of equal to or more than 50 mass % and equal to or less than 65 mass % of the entire composition constituting the adhesive layer 14.

In addition, the inorganic filler (C) preferably consists of the large-grain-diameter alumina and the agglomerate of boron nitride (the inorganic filler (C) preferably does not include any components other than the large-grain-diameter alumina and the agglomerate of boron nitride).

Meanwhile, the adhesive layer 14 preferably does not include a silicone resin. In such a case, it is possible to prevent the generation of siloxane gas.

Next, the properties of the adhesive layer 14 will be described.

The glass transition temperature of the adhesive layer 14 is equal to or lower than −30° C. Among them, the glass transition temperature of the adhesive layer 14 is preferably equal to or lower than −35° C., and more preferably equal to or lower than −40° C. The lower limit value of the glass transition temperature of the adhesive layer 14 is not particularly limited and is, for example, −60° C.

The glass transition temperature of the adhesive layer 14 can be measured as described below on the basis of JIS K7121.

The glass transition temperature is measured using a temperature modulation-type differential scanning calorimeter PYRIS Diamond DSC manufactured by PerkinElmer Japan Co., Ltd. under conditions of a step temperature of 2° C., a temperature-increase rate of 5° C./minute, a temperature-holding time of 1 minute, and a nitrogen atmosphere (20 ml/minute). In addition, the intersection between tangent lines at which a differential heat capacity curve indicated with the temperature in the X axis and the specific heat capacity in the Y axis is stabilized before and after the glass transition temperature was used as the glass transition temperature.

As described above, since the glass transition temperature of the adhesive layer 14 is equal to or lower than −30° C., the adhesive layer 14 turns into a rubber state in a wide temperature range. Therefore, even when a difference is caused between the expansion and shrinkage ratio of the heat-dissipating member 13 and the expansion and shrinkage ratio of the supporting base material 12 (particularly, the heat-transfer layer 123) due to a change in the environmental temperature, it is possible to mitigate the difference using the adhesive layer 14. Therefore, it is possible to produce the apparatus 1 having high durability.

In addition, the elastic modulus (storage elastic modulus) E′ of the adhesive layer 14 at 25° C. is preferably equal to or less than 400 MPa.

Among them, the storage elastic modulus E′ is preferably equal to or less than 300 MPa and, among them, preferably equal to or less than 200 MPa.

As described above, when the storage elastic modulus of the adhesive layer 14 is low, even when an expansion and shrinkage difference is caused between the heat-dissipating member 13 and the supporting base material 12, the adhesive layer 14 deforms and it is possible to mitigate stress generated due to the expansion and shrinkage difference between the heat-dissipating member 13 and the supporting base material 12. Therefore, it is possible to produce an apparatus having high durability.

In addition, from the viewpoint of ensuring the strength of the adhesive layer 14, the storage elastic modulus E′ is equal to or more than 5 MPa and, among them, preferably equal to or more than 10 MPa.

Meanwhile, the storage elastic modulus is measured using a dynamic viscoelasticity measurement instrument.

The storage elastic modulus E′ refers to the value of a storage elastic modulus at 25° C. when the storage elastic modulus is measured at a frequency of 1 Hz and a temperature-increase rate of 5 to 10° C./minute in a range of −50° C. to 300° C. with a tensile load applied to the adhesive layer 14.

In addition, the adhesive layer 14 is capable of efficiently transferring heat. Specifically, the thermal conductivity C1 of the adhesive layer 14 in the thickness direction (the lamination direction of the respective members in the apparatus 1) is preferably equal to or more than 3 W/m·K and the thermal conductivity C2 of the adhesive layer 14 in the in-plane direction is preferably equal to or more than 4 W/m·K and, among them, more preferably equal to or more than 5 W/m·K. In addition, |C1−C2|≦2 is preferred. Meanwhile, the lower limit value of |C1−C2| is not particularly limited and is, for example, 0.

By adopting the above conditions, the thermal conductivity of the adhesive layer 14 becomes high in both the in-plane direction and the thickness direction and it is possible to decrease the difference between the thermal conductivity of the adhesive layer 14 in the in-plane direction and the thermal conductivity of the adhesive layer in the thickness direction. Therefore, heat from the element 11 spreads throughout the adhesive layer 14 and it is possible to facilitate the transfer of heat to the heat-dissipating member 13 through the adhesive layer 14.

Among them, the thermal conductivity C1 of the adhesive layer 14 in the thickness direction is preferably equal to or more than 5 W/m·K. The upper limit value of the thermal conductivity C1 of the adhesive layer 14 in the thickness direction is not particularly limited and is, for example, 60 W/m·K.

Furthermore, the thermal conductivity C2 of the adhesive layer 14 in the in-plane direction is preferably equal to or more than 7 W/m·K. In addition, the upper limit value of the thermal conductivity C2 of the adhesive layer 14 in the in-plane direction is not particularly limited and is, for example, 60 W/m·K.

Next, the heat-dissipating member 13 will be described.

The heat-dissipating member 13 is, for example, a heat sink made of a metal such as Al.

The above-described apparatus 1 can be manufactured as described below.

First, the heat-dissipating member 13 is prepared.

After that, the adhesive layer 14 is provided on the heat-dissipating member 13. At this time, the liquid-phase composition for an adhesive, which forms the adhesive layer 14, may be applied onto the heat-dissipating member 13 or it is also possible to shape the composition for an adhesive into a sheet shape in advance and attach the sheet to the heat-dissipating member 13.

The resin composition for an adhesive is in an uncured state (A stage) and has a glass transition temperature (Tg) of equal to or lower than −30° C. after being cured at 150° C. for 1 hour.

In addition, the composition for an adhesive preferably has a storage elastic modulus E′ at 25° C. of equal to or less than 400 MPa after being cured at 150° C. for 1 hour. The preferred range of the storage elastic modulus and the Tg of the composition for an adhesive are the same as those of the adhesive layer 14.

The composition for an adhesive is in a liquid phase. In addition, the composition for an adhesive does not include a solvent and the viscosity at 25° C., which is measured using an E-type viscometer, is preferably equal to or more than 5 Pa-s and equal to or less than 70 Pa·s and, among them, preferably equal to or less than 60 Pa·s.

When the viscosity at 25° C. measured using an E-type viscometer is set to equal to or less than 70 Pa·s, it becomes easy to apply the composition for an adhesive. In addition, since the composition for an adhesive does not include a solvent, it is possible to prevent a solvent from volatilizing in the adhesive layer 14, prevent the generation of voids, and thus prevent the degradation of heat-transferring properties.

The viscosity is measured as described below.

The viscosity is measured using an E-type viscometer at a measurement temperature of 25° C., a cone angle of 3 degrees, and a rotation rate of 5.0 rpm.

In addition, the thixotropic index (the ratio of the viscosity at a rotation speed of 1 rpm to the viscosity at 5 rpm in an E-type viscometer) of the composition for an adhesive is preferably in a range of equal to or more than 1.1 and equal to or less than 3.0. When the thixotropic index is set to equal to or more than 1.1, there is an effect that prevents the sedimentation of the filler and, when the thixotropic index is set to equal to or less than 3.0, there is an effect that improves workability.

In addition, the sheet made of the composition for an adhesive preferably has Tg of equal to or lower than −30° C. after being cured at 150° C. for 1 hour and a storage elastic modulus E′ at 25° C. of equal to or less than 400 MPa after being cured at 150° C. for 1 hour. The preferred range of the storage elastic modulus and the Tg of the sheet are the same as those of the adhesive layer 14.

Furthermore, since the sheet forms the adhesive layer 14, it is preferable that, after the sheet is cured at 150° C. for 1 hour, the thermal conductivity C1 of the sheet in the thickness direction is equal to or more than 3 W/m-K, the thermal conductivity C2 of the sheet in the in-plane direction is equal to or more than 4 W/m·K, and |C1−C2|≦2. The preferred ranges of C1 and C2 are the same as those of the adhesive layer 14. Meanwhile, the sheet before being cured is in a semi-cured state (B-stage state).

After that, the heat-transfer layer 123 is provided on the sheet or the composition for an adhesive and then the sheet or the composition for an adhesive is cured at 150° C. for 1 hour. Therefore, the adhesive layer 14 is formed. The adhesive layer 14 turns into a fully-cured state.

Next, the insulating sheet 122 and the lead frame 121 are disposed on the heat-transfer layer 123. After that, the die pad section in the lead frame 121 and the element 11 are joined together through the solder 15. After that, the element 11 is encapsulated using an encapsulating material 16.

Meanwhile, the present invention is not limited to the above-described embodiment and any modification, improvement, and the like are included in the scope of the present invention as long as the object of the present invention can be achieved.

For example, in the above-described embodiment, the supporting base material 12 includes the lead frame 121, the insulating sheet 122, and the heat-transfer layer 123, but the present invention is not limited thereto. For example, as shown in FIG. 2, a ceramic substrate may be used as a supporting base material 22. In this case, the adhesive layer 14 adheres the ceramic substrate to the heat-dissipating member 13.

In addition, the semiconductor element is used as the element 11, but the present invention is not limited thereto and the element may be any element that generates heat and also may be an optical element such as a light-emitting element.

### EXAMPLES

Next, examples of the present invention will be described.

### Example 1

21 g of diethylene glycol diglycidyl ether (EX-851 manufactured by Nagase ChemteX Corporation, represented by Formula (7)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The composition for an adhesive was applied onto a mat surface of a 35 μm-thick electrodeposited copper foil GTSMP (product name of Furukawa Circuit Foil Co., Ltd.) so that the dried film thickness reached 100 μm and was dried at 80° C. for 10 minutes, thereby obtaining a B-stage adhesive sheet. After that, the above-described adhesive sheet-attached copper foil and the 35 μm-thick electrodeposited copper foil GTSMP (product name of Furukawa Circuit Foil Co., Ltd.) were press-adhered to each other at 150° C. and 2 MPa for 60 minutes, thereby producing a laminate. The characteristics of the laminate were measured and the results were described in Table 1.

Meanwhile, the methods for measuring the characteristics described in Table 1 are as described below. The methods shall apply to examples and comparative examples described below.

1. Characteristics of Composition for Adhesive

(1) Viscosity

The viscosity was measured using an E-type viscometer at a measurement temperature of 25° C., a cone angle of 3 degrees, and a rotation rate of 5.0 rpm.

(2) Thixotropic Property

The viscosity was measured using an E-type viscometer at a measurement temperature of 25° C., a cone angle of 3 degrees, and a rotation rate of 5.0 rpm.

In addition, the viscosity was measured using the E-type viscometer at a measurement temperature of 25° C., a cone angle of 3 degrees, and a rotation rate of 1.0 rpm. Furthermore, the ratio (A/B) of the viscosity B at a rotation speed of 1 rpm to the viscosity A at 5 rpm in the E-type viscometer was used as the thixotropic value.

2. Characteristics of cured substance

(1) Glass Transition Temperature (Tg)

The glass transition temperature was measured as described below on the basis of JIS K7121.

The electrodeposited copper foil GTSMP was peeled off from the laminate manufactured through 60-minute press-adhering at 150° C. and 2 MPa, thereby obtaining an adhesive layer. In addition, the glass transition temperature was measured using a temperature modulation-type differential scanning calorimeter PYRIS Diamond DSC manufactured by PerkinElmer Japan Co., Ltd. under conditions of a step temperature of 2° C., a temperature-increase rate of 5° C./minute, a temperature-holding time of 1 minute, and a nitrogen atmosphere (20 ml/minute). The intersection between tangent lines at which a differential heat capacity curve indicated with the temperature in the X axis and the specific heat capacity in the Y axis was stabilized before and after the glass transition temperature was used as the glass transition temperature.

(2) Storage Elastic Modulus (E′)

The electrodeposited copper foil GTSMP was peeled off from the laminate manufactured through 60-minute press-adhering at 150° C. and 2 MPa, thereby obtaining an adhesive layer. In addition, the adhesive layer was cut so as to obtain an 8×20 mm specimen. The storage elastic modulus was measured in a temperature range of −50° C. to 300° C. using a dynamic viscoelasticity measurement instrument in a tensile mode at a frequency of 1 Hz and a temperature-increase rate of 5° C./minute. And then, the storage elastic modulus at 25° C. was obtained.

(3) Thermal Conductivity

The electrodeposited copper foil GTSMP was peeled off from the laminate manufactured through 60-minute press-adhering at 150° C. and 2 MPa, thereby obtaining an adhesive layer (thickness: 100 μm). In addition, the thermal conductivity of the adhesive layer was measured in the thickness direction and the in-plane direction. Specifically, the thermal conductivity was computed using the following expression, in which the thermal diffusion coefficient (α) was measured using a laser flash method (a halftime method), the specific heat (Cp) was measured using a DSC method, and the density (ρ) was measured according to JIS-K-6911. The unit of the thermal conductivity is W/m·K.

thermal conductivity [W/m·K]=α [mm²/s]×Cp [J/g·K]×ρ [g/cm³]

### Example 2

24 g of diethylene glycol diglycidyl ether (EX-851 manufactured by Nagase ChemteX Corporation, represented by Formula (7)), 10 g of polybutadiene-denatured epoxy resin (PB-3600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 3

18 g of diethylene glycol diglycidyl ether (EX-851 manufactured by Nagase ChemteX Corporation, represented by Formula (7)), 16 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 4

21 g of diethylene glycol diglycidyl ether (EX-851 manufactured by Nagase ChemteX Corporation, represented by Formula (7)), 13 g of polybutadiene-denatured epoxy resin (PB-3600 manufactured by Daicel Corporation, represented by Formula (1)), 1 g of 1,2-dimethylimidazole (1,2-DMZ manufactured by Shikoku Chemicals Corporation), 22 g of boron nitride (SP-3 manufactured by Denki Kagaku Kogyo Kabushiki Kaisha, average particle diameter: 4 μm), and 43 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 5

21 g of diethylene glycol diglycidyl ether (EX-851 manufactured by Nagase ChemteX Corporation, represented by Formula (7)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 20 g of boron nitride (SP-3 manufactured by Denki Kagaku Kogyo Kabushiki Kaisha, average particle diameter: 4 μm), and 45 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 6

21 g of diethylene glycol diglycidyl ether (EX-851 manufactured by Nagase ChemteX Corporation, represented by Formula (7)), 13 g of polybutadiene-denatured epoxy resin (PB-3600 manufactured by Daicel Corporation, represented by Formula (1)), 1 g of 1,2-dimethylimidazole (1,2-DMZ manufactured by Shikoku Chemicals Corporation), 17 g of boron nitride (SP-3 manufactured by Denki Kagaku Kogyo Kabushiki Kaisha, average particle diameter: 4 μm), and 48 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 7

27 g of diethylene glycol diglycidyl ether (EX-851 manufactured by Nagase ChemteX Corporation, represented by Formula (7)), 17 g of polybutadiene-denatured epoxy resin (PB-3600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 37 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 8

21 g of diethylene glycol diglycidyl ether (EX-851 manufactured by Nagase ChemteX Corporation, represented by Formula (7)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (UHP-S1 manufactured by Showa Denko K.K., average particle diameter: 7 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 9

21 g of diethylene glycol diglycidyl ether (EX-851 manufactured by Nagase ChemteX Corporation, represented by Formula (7)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (AA-18 manufactured by Sumitomo Chemical Co., Ltd., average particle diameter: 18 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 10

21 g of diethylene glycol diglycidyl ether (EX-851 manufactured by Nagase ChemteX Corporation, represented by Formula (7)), 13 g of polybutadiene-denatured epoxy resin (PB-3 600 manufactured by Daicel Corporation, represented by Formula (1)), 1 g of 1-benzyl-2-phenylimidazole (1B2PZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 11

21 g of 1,6-hexanediol diglycidyl ether (EX-212 manufactured by Nagase ChemteX Corporation, represented by Formula (2)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 12

21 g of neopentyl glycol diglycidyl ether (EX-211 manufactured by Nagase ChemteX Corporation, represented by Formula (6)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 13

21 g of 1,4-butanediol diglycidyl ether (EX-214 manufactured by Nagase ChemteX Corporation, represented by Formula (3)), 13 g of polybutadiene-denatured epoxy resin (PB-3 600 manufactured by Daicel Corporation, represented by Formula (1)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Example 14

21 g of diethylene glycol diglycidyl ether (EX-851 manufactured by Nagase ChemteX Corporation, represented by Formula (7)), 13 g of polybutadiene-denatured epoxy resin (R-45EPT manufactured by Nagase ChemteX Corporation, represented by Formula (9)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Comparative Example 1

13 g of polybutadiene-denatured epoxy resin (PB-3600 manufactured by Daicel Corporation, represented by Formula (1)), 21 g of bisphenol A-type epoxy resin (YD-128 manufactured by Nippon Steel & Sumikin Chemical Co., Ltd.), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Comparative Example 2

34 g of bisphenol A-type epoxy resin (YD-128 manufactured by Nippon Steel & Sumikin Chemical Co., Ltd.), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Comparative Example 3

34 g of bisphenol F-type epoxy resin (YDF-170 manufactured by Nippon Steel & Sumikin Chemical Co., Ltd.), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

### Comparative Example 4

34 g of diethylene glycol diglycidyl ether (EX-851 manufactured by Nagase ChemteX Corporation, represented by Formula (7)), 1 g of 1,2-dimethylimidazole (1,2-DMZ manufactured by Shikoku Chemicals Corporation), 18 g of boron nitride (SP-3 manufactured by Denki Kagaku Kogyo Kabushiki Kaisha, average particle diameter: 4 μm), and 47 g of alumina (DAM-45 manufactured by Denki Kagaku Kogyo Kabushiki Kaisha, average particle diameter: 45 μm) were put into a 250 ml disposable cup, were stirred for 1 hour, and then were stirred and kneaded for 5 minutes using a small-size stirring and defoaming apparatus AWATORI RENTARO MX-201 (product name of Thinky), thereby obtaining a composition for an adhesive. The subsequent steps were the same as in Example 1.

(Evaluation)

Semiconductor devices shown in FIG. 1 were manufactured using the resin compositions for an adhesive of Examples 1 to 14 and Comparative Examples 1 to 4. Here, the encapsulating material was not provided.

The resin composition for an adhesive was applied to an aluminum heat-dissipating member 13 and an adhesive layer was provided. After that, a Cu heat-transfer layer 123 was provided on the composition for an adhesive and then the composition for an adhesive was cured at 150° C. for 1 hour. Furthermore, an insulating sheet 122 and a Cu lead frame 121 were disposed on the heat-transfer layer 123. F-Co TM sheet HF manufactured by Furukawa Circuit Foil Co., Ltd. was used as the insulating sheet 122. After that, a die pad section in the lead frame 121 and an element 11 were joined together through a solder 15 (a material of Sn-3.0Ag-0.5Cu).

As described above, for each of the examples and the comparative examples, 10 semiconductor devices were prepared and heat cycle tests were carried out. In the heat cycle test, −40° for 7 minutes to +175° C. for 7 minutes formed one cycle and the cycle was repeated 3000 times. Whether or not the adhesive layer was peeled off from the heat-dissipating member 13 or the heat-transfer layer 123 after the heat cycle test was observed and the number of semiconductor devices in which the adhesive layer was peeled off was counted.

The results are described in Table 1.

In Examples 1 to 14, the adhesive layer was not peeled off. Therefore, it was possible to reliably transfer heat from the semiconductor element to the heat-dissipating member and an apparatus having high durability was produced.

On the contrary, in Comparative Examples 1 to 4, the adhesive layer was peeled off. Therefore, it became difficult to transfer heat from the semiconductor element to the heat-dissipating member. Therefore, it is considered that the performance of the semiconductor element was affected.

TABLE 1

| | | | | | Ex. 1 | Ex. 2 | Ex. 3 | Ex. 4 | Ex. 5 | Ex. 6 |
|---|---|---|---|---|---|---|---|---|---|---|
| Blending quantity | Liquid- | Diethylene | EX-851 | | 21 | 24 | 18 | 21 | 21 | 21 |
| (g) | phase epoxy | glycol | | | | | | | | |
| | | diglycidyl | | | | | | | | |
| | | ether | | | | | | | | |
| | Liquid- | 1,6-Hexanediol | EX-212 | | | | | | | |
| | phase epoxy | diglycidyl | | | | | | | | |
| | | ether | | | | | | | | |
| | Liquid- | Neopentyl | EX-211 | | | | | | | |
| | phase epoxy | glycol | | | | | | | | |
| | | diglycidyl | | | | | | | | |
| | | ether | | | | | | | | |
| | Liquid- | 1,4-Butanediol | EX-214 | | | | | | | |
| | phase epoxy | diglycidyl | | | | | | | | |
| | | ether | | | | | | | | |
| | Liquid- | Polybutadiene- | PB-3600 | | 13 | 10 | 16 | 13 | 13 | 13 |
| | phase epoxy | denatured epoxy | | | | | | | | |
| | | resin | | | | | | | | |
| | Liquid- | Polybutadiene- | R-45EPT | | | | | | | |
| | phase epoxy | denatured epoxy | | | | | | | | |
| | | resin | | | | | | | | |
| | Liquid- | Bisphenol | YD-128 | | | | | | | |
| | phase epoxy | A-type epoxy | | | | | | | | |
| | | resin | | | | | | | | |
| | Liquid- | Bisphenol | YDF-170 | | | | | | | |
| | phase epoxy | F-type epoxy | | | | | | | | |
| | | resin | | | | | | | | |
| | Imidazole | 1,2-Dimethyl | 1,2-DMZ | | 1 | 1 | 1 | 1 | 1 | 1 |
| | | imidazole | | | | | | | | |
| | Imidazole | 1-Benzyl-2- | 1B2PZ | | | | | | | |
| | | phenylimidazole | | | | | | | | |
| | Boron nitride | (4 μm) | SP-3 | | 18 | 18 | 18 | 22 | 20 | 17 |
| | Boron nitride | (7 μm) | UHP-S1 | | | | | | | |
| | Alumina | (45 μm) | DAM-45 | | 47 | 47 | 47 | 43 | 45 | 48 |
| | Alumina | (18 μm) | AA-18 | | | | | | | |
| | Total | | | sum | 100 | 100 | 100 | 100 | 100 | 100 |
| Characteristics | Viscosity | | | Pa · s | 52 | 43 | 58 | 70 | 59 | 40 |
| of resin | Thixotropic | 5 rpm/1 rpm | | | 1.3 | 1.2 | 2.1 | 2.2 | 2.1 | 1.3 |
| composition | value | | | | | | | | | |
| Characteristics | Tg | | | ° C. | −36 | −41 | −32 | −32 | −36 | −36 |
| of cured | Storage | | 25° C. | MPs | 280 | 385 | 195 | 185 | 188 | 300 |
| substance | elastic | | | | | | | | | |
| | modulus | | | | | | | | | |
| | Thermal | | | W/m · K | 3.5 | 3.5 | 3.4 | 3.7 | 3.7 | 3.4 |
| | conductivity | | | | | | | | | |
| | in thickness | | | | | | | | | |
| | direction C1 | | | | | | | | | |
| | Thermal | | | W/m · K | 5.1 | 4.9 | 4.9 | 5.5 | 5.4 | 4.9 |
| | conductivity | | | | | | | | | |
| | in in-plane | | | | | | | | | |
| | direction C2 | | | | | | | | | |
| | \|C1 − C2\| | | | W/m · K | 1.6 | 1.4 | 1.5 | 1.8 | 1.7 | 1.5 |
| Results of heat cycle tests | | | | | 0 | 0 | 0 | 0 | 0 | 0 |
| | | | | | Ex. 7 | Ex. 8 | Ex. 9 | Ex. 10 | Ex. 11 | Ex. 12 |
| Blending quantity | Liquid- | Diethylene | EX-851 | | 27 | 21 | 21 | 21 | | |
| (g) | phase epoxy | glycol | | | | | | | | |
| | | diglycidyl | | | | | | | | |
| | | ether | | | | | | | | |
| | Liquid- | 1,6-Hexanediol | EX-212 | | | | | | 21 | |
| | phase epoxy | diglycidyl | | | | | | | | |
| | | ether | | | | | | | | |
| | Liquid- | Neopentyl | EX-211 | | | | | | | 21 |
| | phase epoxy | glycol | | | | | | | | |
| | | diglycidyl | | | | | | | | |
| | | ether | | | | | | | | |
| | Liquid- | 1,4-Butanediol | EX-214 | | | | | | | |
| | phase epoxy | diglycidyl | | | | | | | | |
| | | ether | | | | | | | | |
| | Liquid- | Polybutadiene- | PB-3600 | | 17 | 13 | 13 | 13 | 13 | 13 |
| | phase epoxy | denatured epoxy | | | | | | | | |
| | | resin | | | | | | | | |
| | Liquid- | Polybutadiene- | R-45EPT | | | | | | | |
| | phase epoxy | denatured epoxy | | | | | | | | |
| | | resin | | | | | | | | |
| | Liquid- | Bisphenol | YD-128 | | | | | | | |
| | phase epoxy | A-type epoxy | | | | | | | | |
| | | resin | | | | | | | | |
| | Liquid- | Bisphenol | YDF-170 | | | | | | | |
| | phase epoxy | F-type epoxy | | | | | | | | |
| | | resin | | | | | | | | |
| | Imidazole | 1,2-Dimethyl | 1,2-DMZ | | 1 | 1 | 1 | | 1 | 1 |
| | | imidazole | | | | | | | | |
| | Imidazole | 1-Benzyl-2- | 1B2PZ | | | | | 1 | | |
| | | phenylimidazole | | | | | | | | |
| | Boron nitride | (4 μm) | SP-3 | | 18 | | 18 | 18 | 18 | 18 |
| | Boron nitride | (7 μm) | UHP-S1 | | | 18 | | | | |
| | Alumina | (45 μm) | DAM-45 | | 37 | 47 | | 47 | 47 | 47 |
| | Alumina | (18 μm) | AA-18 | | | | 47 | | | |
| | Total | | | sum | 100 | 100 | 100 | 100 | 100 | 100 |
| Characteristics | Viscosity | | | Pa · s | 40 | 42 | 60 | 54 | 48 | 48 |
| of resin | Thixotropic | 5 rpm/1 rpm | | | 1.2 | 1.2 | 1.7 | 1.4 | 1.1 | 1.1 |
| composition | value | | | | | | | | | |
| Characteristics | Tg | | | ° C. | −34 | −36 | −36 | −31 | −31 | −30 |
| of cured | Storage | | 25° C. | MPs | 186 | 300 | 300 | 280 | 290 | 320 |
| substance | elastic | | | | | | | | | |
| | modulus | | | | | | | | | |
| | Thermal | | | W/m · K | 3.1 | 3.4 | 3.3 | 3.5 | 3.5 | 3.3 |
| | conductivity | | | | | | | | | |
| | in thickness | | | | | | | | | |
| | direction C1 | | | | | | | | | |
| | Thermal | | | W/m · K | 4.3 | 4.9 | 4.8 | 5.1 | 4.7 | 4.7 |
| | conductivity | | | | | | | | | |
| | in in-plane | | | | | | | | | |
| | direction C2 | | | | | | | | | |
| | \|C1 − C2\| | | | W/m · K | 1.2 | 1.5 | 1.5 | 1.6 | 1.2 | 1.4 |
| Results of heat cycle tests | | | | | 0 | 0 | 0 | 0 | 0 | 0 |
| | | | | | | | Comp | Comp | Comp | Comp |
| | | | | | Ex. 13 | Ex. 14 | Ex. 1 | Ex. 2 | Ex. 3 | Ex. 4 |
| Blending quantity | Liquid- | Diethylene | EX-851 | | | 21 | | | | 34 |
| (g) | phase epoxy | glycol | | | | | | | | |
| | | diglycidyl | | | | | | | | |
| | | ether | | | | | | | | |
| | Liquid- | 1,6-Hexanediol | EX-212 | | | | | | | |
| | phase epoxy | diglycidyl | | | | | | | | |
| | | ether | | | | | | | | |
| | Liquid- | Neopentyl | EX-211 | | | | | | | |
| | phase epoxy | glycol | | | | | | | | |
| | | diglycidyl | | | | | | | | |
| | | ether | | | | | | | | |
| | Liquid- | 1,4-Butanediol | EX-214 | | 21 | | | | | |
| | phase epoxy | diglycidyl | | | | | | | | |
| | | ether | | | | | | | | |
| | Liquid- | Polybutadiene- | PB-3600 | | 13 | | 13 | | | |
| | phase epoxy | denatured epoxy | | | | | | | | |
| | | resin | | | | | | | | |
| | Liquid- | Polybutadiene- | R-45EPT | | | 13 | | | | |
| | phase epoxy | denatured epoxy | | | | | | | | |
| | | resin | | | | | | | | |
| | Liquid- | Bisphenol | YD-128 | | | | 21 | 34 | | |
| | phase epoxy | A-type epoxy | | | | | | | | |
| | | resin | | | | | | | | |
| | Liquid- | Bisphenol | YDF-170 | | | | | | 34 | |
| | phase epoxy | F-type epoxy | | | | | | | | |
| | | resin | | | | | | | | |
| | Imidazole | 1,2-Dimethyl | 1,2-DMZ | | 1 | 1 | 1 | 1 | 1 | 1 |
| | | imidazole | | | | | | | | |
| | Imidazole | 1-Benzyl-2- | 1B2PZ | | | | | | | |
| | | phenylimidazole | | | | | | | | |
| | Boron nitride | (4 μm) | SP-3 | | 18 | 18 | 18 | 18 | 18 | 18 |
| | Boron nitride | (7 μm) | UHP-S1 | | | | | | | |
| | Alumina | (45 μm) | DAM-45 | | 47 | 47 | 47 | 47 | 47 | 47 |
| | Alumina | (18 μm) | AA-18 | | | | | | | |
| | Total | | | sum | 100 | 100 | 100 | 100 | 100 | 100 |
| Characteristics | Viscosity | | | Pa · s | 53 | 70 | 120 | 80 | 60 | 40 |
| of resin | Thixotropic | 5 rpm/1 rpm | | | 1.2 | 2.1 | 1.8 | 2.3 | 2.3 | 1.2 |
| composition | value | | | | | | | | | |
| Characteristics | Tg | | | ° C. | −31 | −44 | −10 | 65 | 80 | −5 |
| of cured | Storage | | 25° C. | MPs | 320 | 178 | 450 | 1880 | 2020 | 440 |
| substance | elastic | | | | | | | | | |
| | modulus | | | | | | | | | |
| | Thermal | | | W/m · K | 3.3 | 3.3 | 3.5 | 3.5 | 3.5 | 3.3 |
| | conductivity | | | | | | | | | |
| | in thickness | | | | | | | | | |
| | direction C1 | | | | | | | | | |
| | Thermal | | | W/m · K | 4.8 | 4.6 | 5.1 | 5.1 | 5.1 | 4.7 |
| | conductivity | | | | | | | | | |
| | in in-plane | | | | | | | | | |
| | direction C2 | | | | | | | | | |

| | | | | | | | |
|---|---|---|---|---|---|---|---|
| \|C1 − C2\| | W/m · K | 1.5 | 1.3 | 1.6 | 1.6 | 1.6 | 1.4 |

| | | | | | | |
|---|---|---|---|---|---|---|
| Results of heat cycle tests | 0 | 0 | 2 | 10 | 10 | 3 |

The present application claims priority on the basis of Japanese Patent Application No. 2013-045500, filed on Mar. 7, 2013, and the content thereof is incorporated herein by reference.

1. An apparatus comprising:
a supporting base material that supports an element;
a heat-dissipating member on which the supporting base material is installed; and
an adhesive layer disposed between the heat-dissipating member and the supporting base material,
wherein a glass transition temperature of the adhesive layer is equal to or lower than −30° C.

2. The apparatus according to claim 1,
wherein the adhesive layer comprises a cured curable resin.

3. The apparatus according to claim 2,
wherein the adhesive layer does not comprise a silicone resin.

4. The apparatus according to claim 1,
wherein the adhesive layer has a storage elastic modulus E′ at 25° C. of equal to or less than 400 MPa.

5. The apparatus according to claim 1,
wherein the adhesive layer comprises a resin component and a heat-transferring filler, and,
as the heat-transferring filler, comprises alumina having an average particle diameter of equal to or more than 18 μm and an agglomerate of boron nitride particles having an average particle diameter of equal to or less than 7 μm.

6. The apparatus according to claim 1,
wherein the adhesive layer comprises a curable resin and a heat-transferring filler, and,
the curable resin comprises any one or more of an epoxy resin, an unsaturated polyester, and an acrylic resin.

7. The apparatus according to claim 1,
wherein a thickness of the adhesive layer is equal to or less than 100 μm.

8. A composition for an adhesive that adheres a supporting base material that supports an element and a heat-dissipating member together,
wherein a glass transition temperature is equal to or lower than −30° C. after the composition is cured at 150° C. for 1 hour.

9. The composition for an adhesive according to claim 8,
wherein the composition for an adhesive is thermally cured and adheres the supporting base material to the heat-dissipating member,
the composition for an adhesive comprises a thermosetting resin, and
the composition for an adhesive does not comprise a silicone resin.

10. The composition for an adhesive according to claim 8,
wherein a storage elastic modulus E′ at 25° C. is equal to or less than 400 MPa after the composition is cured at 150° C. for 1 hour.

11. The composition for an adhesive according to claim 8,
wherein the composition for an adhesive does not comprise a solvent, and
a viscosity at 25° C. measured using an E-type viscometer is equal to or less than 70 Pa·s.

12. An adhesive sheet obtained by shaping the composition for an adhesive according to claim 8 into a sheet shape, comprising:
a resin component; and
a heat-transferring filler,
wherein, after the sheet is cured at 150° C. for 1 hour, a thermal conductivity C1 in a thickness direction is equal to or more than 3 W/m·K,
a thermal conductivity C2 in an in-plane direction is equal to or more than 4 W/m·K, and |C1−C2|≦2 W/m·K.
